(19) United States
(12) Patent Application Publication
(10) Pub. No.: US 2025/0275196 A1
(43) Pub. Date: Aug. 28, 2025

(54) SELECTIVE DEPOSITION METHOD AND SEMICONDUCTOR STRUCTURE MANUFACTURED USING THE SAME

(71) Applicant: TAIWAN SEMICONDUCTOR MANUFACTURING COMPANY, LTD., Hsinchu (TW)

(72) Inventors: Yi-Hsiu CHEN, Hsinchu (TW); Hsu-Kai CHANG, Hsinchu (TW); Hui Ying TAN, Hsinchu (TW); Kenichi SANO, Hsinchu (TW)

(73) Assignee: TAIWAN SEMICONDUCTOR MANUFACTURING COMPANY, LTD., Hsinchu (TW)

(21) Appl. No.: 18/589,669

(22) Filed: Feb. 28, 2024

(51) Int. Cl. H01L 29/06; C23C 16/40; C23C 16/455; H01L 21/8234; H01L 29/08; H01L 29/423; H01L 29/66; H01L 29/775; H01L 29/786

(52) U.S. Cl. CPC H10D 62/118; C23C 16/403; C23C 16/405; C23C 16/45553; H10D 30/014; H10D 30/43; H10D 30/6735; H10D 30/6757; H10D 62/151; H10D 64/017; H10D 64/018; H10D 64/021; H10D 84/013; H10D 84/038

(57) ABSTRACT

A method for manufacturing a semiconductor structure includes: forming a patterned structure including an interfacial layer and two dielectric spacers, a first surface of the interfacial layer and two second surfaces of the two dielectric spacers being arranged to border a cavity, the first surface being formed with first functional groups, the two second surfaces being formed with second functional groups; selectively forming a first self-assembled monolayer on the first surface of the interfacial layer; selectively forming two dummy layers respectively on the two second surfaces of the two dielectric spacers; removing the first self-assembled monolayer to expose the first surface of the interfacial layer; selectively forming two second self-assembled monolayers respectively on the two dummy layers; and selectively forming a gate dielectric layer on the first surface of the interfacial layer.

### BACKGROUND

With rapid development of semiconductor technology, critical dimension (CD) of transistors keeps shrinking, and a distance between two conductive elements continuously reduces, resulting in an increased parasitic capacitance between the two conductive elements Therefore, reduction in the parasitic capacitance generated in an integrated circuit is required in order to alleviate resistance-capacitance (RC) time delay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 26 illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

During formation of a gate dielectric layer on an interfacial layer of a transistor, the gate dielectric layer may be also formed on gate spacers of the transistor because a precursor used for forming the gate dielectric layer has a similar affinity to both the interfacial layer (which may be made of silicon oxide) and the gate spacers (which may be made of silicon oxynitride or silicon nitride). In such case, a parasitic capacitance formed between a gate electrode and a source/drain contact of the transistor may be relatively high due to the presence of the gate dielectric layer (which may be made of a high dielectric constant (high-k) material) between the gate electrode and the source/drain contact. Therefore, the present disclosure is directed to a method for selectively depositing a dielectric layer, and a semiconductor structure manufactured thereby. In such semiconductor structure, the dielectric layer (which may be a gate dielectric layer made of a high-k dielectric material) is selectively formed on an interfacial layer while leaving two gate spacers exposed from the dielectric layer. In view of a parasitic capacitance between a gate electrode and each of two source/drain contact depends on the permittivity (or dielectric constant) of dielectric material(s) located therebetween, since the high-k dielectric layer is absent between the gate electrode and each of the two source/drain contacts, the parasitic capacitance may be effectively reduced, thereby improving the device performance of the semiconductor structure due to a reduced resistance-capacitance delay (RC delay). The semiconductor structure may be configured as a planar field effect transistor (FET), a fin-type field effect transistor (FinFET), a gate-all-around field effect transistor (GAAFET), complementary field-effect transistors (CFET) structure which includes two GAAFETs stacked on one another in a Z direction, or a fork-sheet structure which includes two GAAFETs spaced part from each other in a Y direction transverse to the Z direction through a wall portion. In the following, the GAAFET is exemplarily formed for the purpose of illustrating the method of the present disclosure.

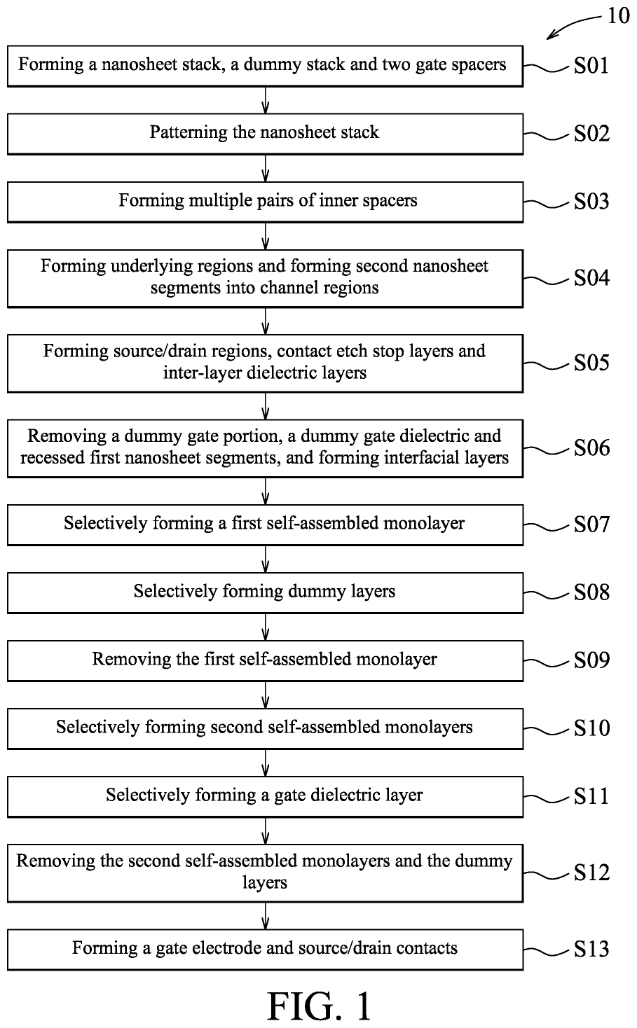

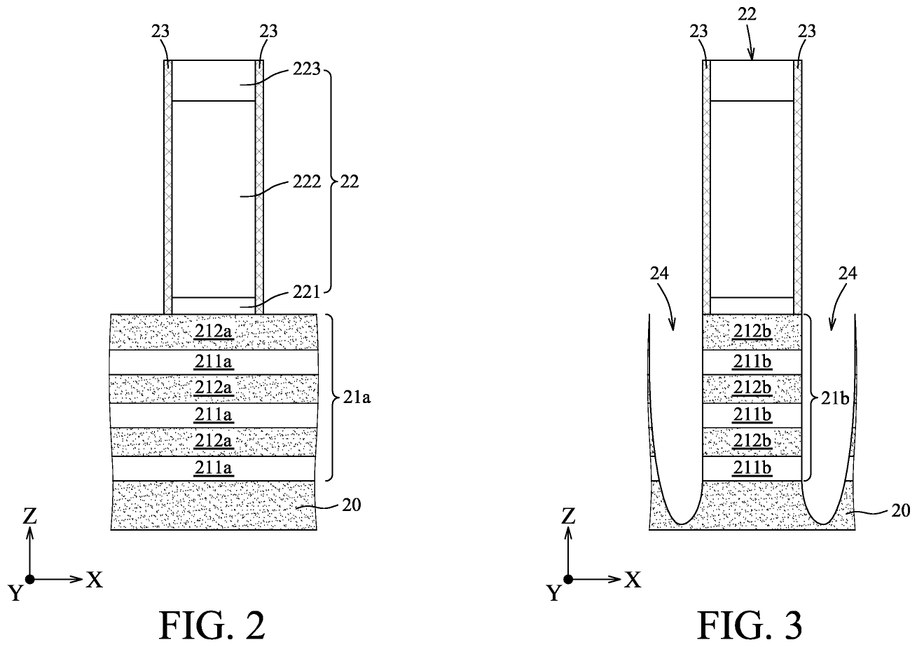

FIG. 1 is a flow diagram illustrating a method 10 for manufacturing a semiconductor structure (for example, but not limited to, a semiconductor structure 50 shown in FIG. 26) in accordance with some embodiments. FIGS. 2 to 26 illustrate schematic views of intermediate stages of the method 10 in accordance with some embodiments.

Referring to FIG. 1 and the example illustrated in FIG. 2, the method 10 begins at step S01, where a nanosheet stack 21a is formed on a substrate 20, a dummy stack 22 is formed over the nanosheet stack 21a, and then two gate spacers 23 are respectively formed at two opposite sides of the dummy stack 22 in an X direction transverse to the Y and Z directions. In some embodiments, the X, Y and Z directions are perpendicular to each other.

In some embodiments, the substrate 20 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 20 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 20 may be configured as a semiconductor-on-insulator substrate. In some embodiments, the semiconductor material in the substrate 20 may be un-doped, or may be doped with impurities (e.g., n-type impurities or p-type impurities) to form a well implantation region for the semiconductor structure 50. Other suitable materials and configurations for the substrate 20 are within the contemplated scope of the present disclosure.

In some embodiments, the nanosheet stack 21a is elongated in the X direction, and includes a plurality of first nanosheets 211a (three of which are shown in FIG. 2) and a plurality of second nanosheets 212a (three of which are shown in FIG. 2) disposed to alternate with the first nanosheets 211a in the Z direction. In some embodiments, an uppermost one of the second nanosheets 212a is disposed over an uppermost one of the first nanosheets 211a opposite to the substrate 20. In some embodiments, a lowermost one of the second nanosheets 212a is spaced apart from the substrate 20 by a lowermost one of the first nanosheets 211a. In some embodiments, the second nanosheets 212a include a semiconductor material. In some embodiments, possible semiconductor materials suitable for the second nanosheets 212a are similar to those for the substrate 20, and thus the details thereof are omitted for the sake of brevity. In some embodiments, the first nanosheets 211a are made of a material different from the semiconductor material of the second nanosheets 212a such that the first nanosheets 211a may be selectively removed with the second nanosheets 212a being substantially intact due to different etching selectivities. In some embodiments, the first nanosheets 211a are made of silicon germanium, and the second nanosheets 212a are made of silicon. Other materials suitable for the first nanosheets 211a and the second nanosheets 212a are within the contemplated scope of the present disclosure. It is noted that the number of the first nanosheets 211a and the number of the second nanosheets 212a may vary according to practical applications. In some other embodiments not shown herein, the number of the first nanosheets 211a and the number of the second nanosheets 212a may be two, four, or more. In some yet other embodiments not shown herein, the nanosheet stack 21a may include a single first nanosheet 211a disposed on the substrate 20, and a single second nanosheet 212a disposed on the first nanosheet 211a opposite to the substrate 20. In some embodiments, formation of the nanosheet stack 21a on the substrate 20 may include (i) forming a film stacking (not shown) on the substrate 20 by chemical vapor deposition (CVD), atomic layer deposition (ALD), an epitaxial growth process (such as molecular-beam epitaxy (MBE), selective area epitaxy (SAE), etc.), or other suitable deposition techniques, and (ii) patterning the film stacking by a photolithography process, thereby obtaining a predetermined dimension of the nanosheet stack 21a in the Y direction.

In some embodiments, the dummy stack 22 is elongated in the Y direction, and includes a dummy gate dielectric 221 disposed over the nanosheet stack 21a, a dummy gate portion 222 disposed on the dummy gate dielectric 221, and a hard mask 223 disposed on the dummy gate portion 222. In some embodiments, the dummy gate dielectric 221 may include silicon oxide, silicon nitride, silicon oxynitride, high dielectric constant (k) materials, other suitable dielectric materials, or combinations thereof. In some embodiments, the dummy gate portion 222 may include polycrystalline silicon, single crystalline silicon, amorphous silicon, or combinations thereof. In some embodiments, the hard mask 223 may include silicon nitride, silicon oxide, silicon oxynitride, or combinations thereof. Other materials suitable for the dummy stack 22 are within the contemplated scope of the present disclosure. In some embodiments, formation of the dummy stack 22 over the nanosheet stack 21a may include (i) sequentially forming a first material layer (not shown) for forming the dummy gate dielectric 221 and a second material layer (not shown) for forming the dummy gate portion 22 over the nanosheet stack 21a by CVD, ALD, physical vapor deposition (PVD), or other suitable deposition techniques, (ii) performing a planarization process (e.g., chemical mechanical polishing) to obtain a planar upper surface of the second material layer, (iii) forming a third material layer (not shown) for forming the hard mask 223 on the planarized second material layer, and (iv) patterning the first material layer, the planarized second material layer and the third material layer by a photolithography process, thereby obtaining the dummy stack 22.

In some embodiments, the gate spacers 23 may be made of a dielectric material which includes a nitride-based material, such as silicon nitride, silicon oxynitride, silicon carbon nitride, silicon oxycarbonnitride, but is not limited thereto. Other dielectric materials suitable for the gate spacers 23 are within the contemplated scope of the present disclosure. In some embodiments, the gate spacers 23 may be formed by CVD, ALD, PVD, or other suitable deposition techniques, followed by an anisotropic etching process to expose the dummy stack 22 and the nanosheet stack 21a.

Referring to FIG. 1 and the example illustrated in FIG. 3, the method 10 proceeds to step S02, where the nanosheet stack 21a (see FIG. 2) is patterned to form two source/drain recesses 24 by an etching technique (for example, but not limited to, dry etching, wet etching, or a combination thereof). FIG. 3 is a schematic sectional view similar to that of FIG. 2, but illustrating the structure after step S02.

The two source/drain recesses 24 are respectively located at two opposite sides of the dummy stack 22 in the X direction. In some embodiments, the substrate 20 is also patterned such that the two source/drain recesses 24 downwardly extend into the substrate 20. After step S02, the patterned nanosheet stack is denoted by the numeral 21b, and includes first nanosheet segments 211b formed from the first nanosheets 211a (see FIG. 2), and second nanosheet segments 212b formed from the second nanosheets 212a (see FIG. 2).

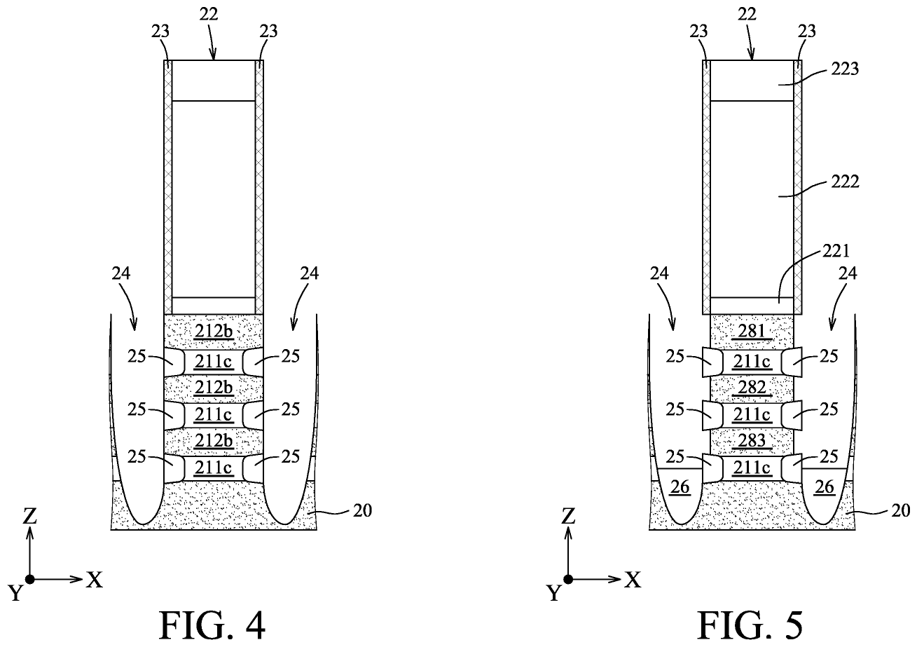

Referring to FIG. 1 and the example illustrated in FIG. 4, the method 10 proceeds to step S03, where multiple pairs of inner spacers 25 are formed. FIG. 4 is a schematic sectional view similar to that of FIG. 3, but illustrating the structure after step S03.

In some embodiments, formation of the inner spacers 25 may include (i) recessing two end portions of each of the first nanosheet segments 211b opposite to each other in the X direction (see FIG. 3) to form lateral recesses (not shown) by an etching process while keeping the second nanosheet segments 212b substantially intact, (ii) depositing a low-k dielectric material for forming the inner spacers 25 to cover each of the recessed first nanosheet segments 211c and fill the lateral recesses by CVD, ALD, PVD, or other suitable deposition techniques, and (iii) remove excess portions of the low-k dielectric material by an anisotropic etching process such that each pair of the inner spacers 24 are respectively formed at two opposite sides of the recessed first nanosheet segments 211c. In some embodiments, the low-k dielectric material for forming the inner spacers 25 may include silicon oxide, silicon nitride, silicon oxynitride, silicon carbonitride, silicon oxycarbide, silicon oxycarbonitride, silicon carbide, and so on. Other low-k dielectric materials suitable for the inner spacers 25 are within the contemplated scope of the present disclosure.

Referring to FIG. 1 and the example illustrated in FIG. 5, the method 10 proceeds to step S04, where two underlying regions 26 are respectively formed in the two source/drain recesses 24, and then the second nanosheet segments 212b (see FIG. 4) are formed into channel regions 281, 282, 283 of the semiconductor structure 50 (see FIG. 26). FIG. 5 is a schematic sectional view similar to that of FIG. 4, but illustrating the structure after step S04.

In some embodiments, the underlying regions 26 are provided for reducing current leakage, and may include an insulating material, an un-doped semiconductor material, or a combination thereof. In some embodiments, the underlying regions 26 may be formed by CVD, ALD, PVD, or other suitable deposition techniques, followed by an etching process so as to prevent two exposed surfaces of each of the second nanosheet segments 212b (see FIG. 4) from being covered by the underlying regions 26. After forming the underlying regions 26, the second nanosheet segments 212b are etched to have a reduced length in the X direction by an etching process, and the etched second nanosheet segments serve as the channel regions 281, 282, 283 of the semiconductor structure 50 (see FIG. 26). It is noted that each of the channel regions 281, 282, 283 may have a length in the X direction which is not smaller than a spaced-apart distance between the gate spacers 23 in the X direction.

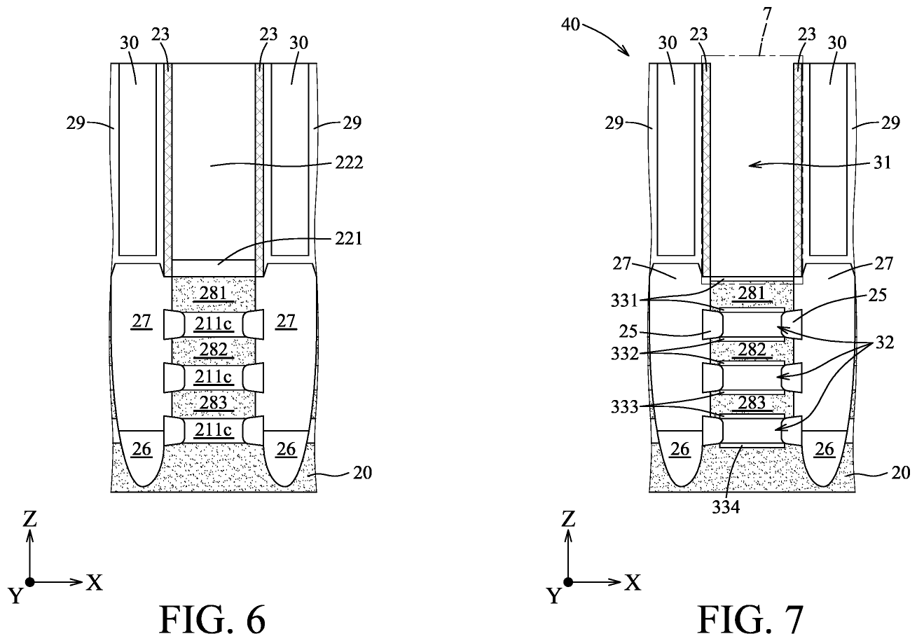

Referring to FIG. 1 and the example illustrated in FIG. 6, the method 10 proceeds to step S05, where two source/drain regions 27 are respectively formed on the two underlying regions 26 to respectively fill the two source/drain recesses 24 (see FIG. 5) such that each of the channel regions 281, 282, 283 extends between the two source/drain regions 27, and then two contact etch stop layers (CESL) 29 and two inter-layer dielectric (ILD) layers 30 are formed. FIG. 6 is a schematic sectional view similar to that of FIG. 5, but illustrating the structure after step S05.

In some embodiments, each of the source/drain regions 27 may include single crystalline silicon, polycrystalline silicon or other suitable materials. In some embodiments, the source/drain regions 27 may be doped with n-type impurities so as to function as source/drain regions of an n-FET. The n-type impurities may be, for example, but not limited to, nitrogen (N), phosphorous (P), arsenic (As), antimony (Sb), other suitable materials, or combinations thereof. In some other embodiments, the source/drain regions 27 may be doped with p-type impurities so as to function as source/drain regions of a p-FET. The p-type impurities may be, for example, but not limited to, boron (B), aluminum (Al), gallium (Ga), indium (In), other suitable materials, or combinations thereof. In some embodiments, each of the source/drain regions 27 may be formed as a multi-layered structure having several sub-layers (not shown) with different doping concentration and/or different dopants. In some embodiments, each of the source/drain regions 27 may be formed as a single layer structure. In some embodiment, the two source/drain regions 27 may be formed by an epitaxial growth process including molecular-beam epitaxy (MBE), an epitaxial deposition/partial etch process, such as a cyclic deposition-etch (CDE) process and/or a selective epitaxial growth (SEG) process, but the disclosure is not limited to such.

In some embodiments, the ILD layers 30 may include a low-k dielectric material, such as silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), or combinations thereof. Other dielectric materials suitable for the ILD layers 30 are within the contemplated scope of the present disclosure. The CESLs 29 are made of a material different from the ILD layers 30. In some embodiments, the CESLs 29 include silicon nitride, carbon-doped silicon nitride, and a combination thereof. Other dielectric materials suitable for the CESLs 29 and the ILD layers 30 are within the contemplated scope of the present disclosure.

In some embodiments, formation of the CESLs 29 and the ILD layers 30 may include (i) forming a fourth material layer (not shown) for forming the two CESLs 29 to cover the two source/drain regions 27, the gate spacers 23 and the dummy stack 22 (see FIG. 5) by a suitable deposition process, (ii) forming a fifth material layer (not shown) for forming the two ILD layers 30 on the fourth material layer by a suitable deposition process, and (iii) performing a planarization process until the dummy gate portion 222 of the dummy stack 22 (see FIG. 5) is exposed such that the fourth material layer is formed into the CESLs 29, and such that the fifth material layer is formed into the ILD layers 30.

Referring to FIG. 1 and the example illustrated in FIG. 7, the method 10 proceeds to step 506, where the dummy gate portion 222 and the dummy gate dielectric 221 (see FIG. 6), and the recessed first nanosheet segments 211c (see FIG. 6) are removed, and then interfacial layers 331, 332, 333, 334 are formed, thereby obtaining a patterned structure 40. FIG. 7 is a schematic sectional view similar to that of FIG. 6, but illustrating the structure after step 506.

In some embodiments, the dummy gate portion 222 and the dummy gate dielectric 221, and the recessed first nanosheet segments 211c may be removed by one or more suitable etching processes (for example but not limited to, a wet etching process, a dry etching process, or a combination thereof).

In some embodiments, as shown in FIG. 7, the interfacial layers 331, 332, 333 are respectively formed around the channel regions 281, 282, 283, and the interfacial layer 324 is formed on the substrate 20. In some embodiments, the interfacial layers 331, 332, 333, 334 include a nitrogen-free dielectric material (i.e., a dielectric material free of nitrogen), for example, but not limited to, silicon oxide. In some embodiments, the interfacial layers 331, 332, 333, 334 may be formed by a thermal oxidation, a wet chemical oxidation, ALD, or other suitable deposition processes. In some embodiments, as shown in FIG. 7, when the interfacial layers 32 are formed by the wet chemical oxidation or the thermal oxidation as abovementioned, surface portions of the channel regions 281, 282, 283 and the substrate 20, which are exposed to an oxidizing agent (e.g., oxygen gas, ozonated aqueous solutions, or a mixture of ammonium hydroxide, hydrogen peroxide and water) used in the thermal oxidation or the wet chemical oxidation, may be oxidized to form the interfacial layers 331, 332, 333, 334. In some embodiments, the interfacial layers 331, 332, 333, 334 are made of a material different from the material of the gate spacers 23.

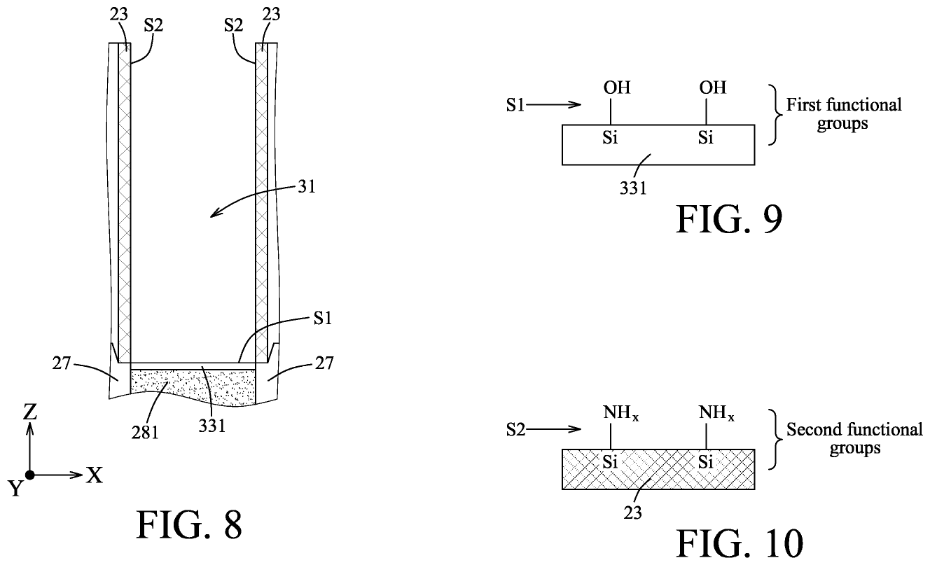

FIG. 8 is a fragmentary enlarged view of area 7 in FIG. 7 in accordance with some embodiments, where the two gate spacers 23 and portions of the two source/drain regions 27, the channel region 281 and the interfacial layer 331 are shown, while other elements are omitted for the sake of brevity. As shown in FIG. 8, a first surface S1 of the interfacial layer 331 and two second surfaces S2 of the two gate spacers 23 are arranged to border a first cavity 31. In some embodiments, as shown in FIG. 7, each pair of the inner spacers 25 and two adjacent corresponding ones of the interfacial layers 331, 332, 333, 334 are arranged to border a second cavity 32, which communicates with the first cavity 31.

FIGS. 9 and 10 are schematic views respectively illustrating a surface portion of each gate spacer 23 and a surface portion of the interfacial layer 331 in accordance with some embodiments. Referring to FIGS. 8 to 10, the first surface S1 is formed with first functional groups, and the second surfaces S2 are formed with second functional groups that are different from the first functional groups. In some embodiments, the first functional groups include hydroxyl groups (—OH), and the second functional groups include amino groups of —NHₓ, where x is 1 or 2. That is, the second functional groups include —NH, —NH₂ or a combination thereof. In some embodiments, when the interfacial layer 331 includes silicon oxide, the first functional groups include Si—OH groups. In some embodiments, when the gate spacers 23 are made of a nitride-based material (such as the examples as described in the previous paragraph), the second functional groups include Si—NH groups, Si—NH₂ groups, or combinations thereof.

In some embodiments, an exposed surface of each of the interfacial layers 331, 332, 333, 334 (see FIG. 7), which borders the corresponding second cavity 32, is also formed with the first functional groups. In some embodiments that the inner spacers 25 (see FIG. 7) includes a nitride-base dielectric material (such as silicon nitride, silicon oxynitride, silicon carbon nitride, silicon oxycarbonnitride), an exposed surface of each of the inner spacers 25, which borders the corresponding second cavity 32, is also formed with the second functional groups.

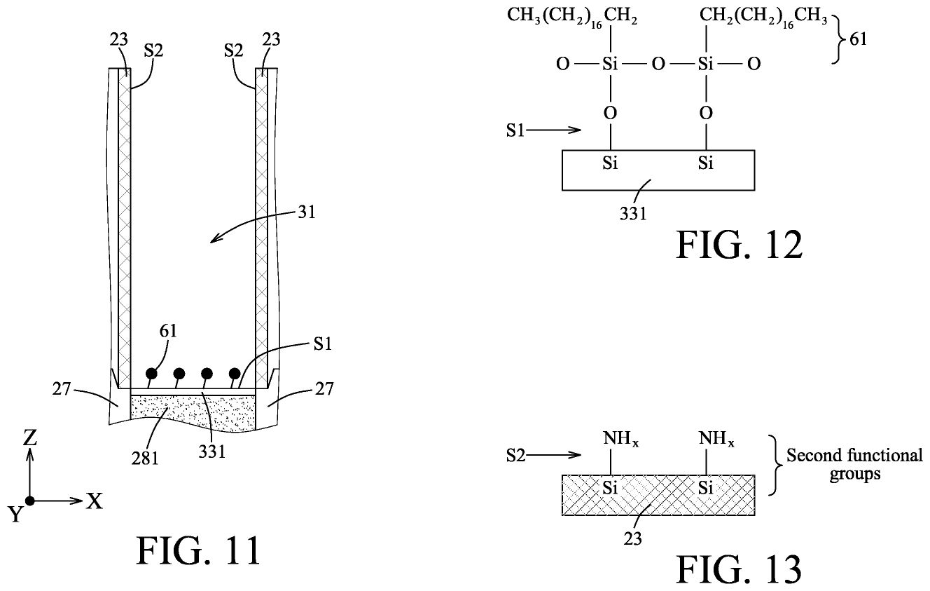

Referring to FIG. 1 and the examples illustrated in FIGS. 11 to 13, the method 10 proceeds to step S07, where a first self-assembled monolayer 61 is selectively formed on the first surface S1 of the interfacial layer 331. FIGS. 11 to 13 are views similar to those of FIGS. 8 to 10, but illustrating the structures after step S07. In some embodiments, as shown in FIG. 13, the functional groups on each second surface S2 after step S07 are the same as those shown in FIG. 10 without being changed.

In some embodiments, the amino groups on the second surface S2 are likely to react with oxidants (e.g., oxygen, water, etc.) in ambient condition, and thus the second surface S2 may be undesirably formed with both amino groups and hydroxyl groups (—OH). As such, the number of the amino groups on the second surface S2 may be insufficient, thereby undesirably affecting the selective formation of the first self-assembled monolayer 61 on the first surface S1. Therefore, in some embodiments, before selectively forming first self-aligned monolayer 61, the gate spacers 23 is subjected to a pretreatment process such that the second functional groups (i.e., the amino groups) are exposed to the first cavity 31. In some embodiments, the pretreatment process is a wet clean process conducted using diluted hydrofluoric acid, which is a mixture of water and concentrated hydrofluoric acid. In some embodiments, in the diluted hydrofluoric acid, a volumetric ratio of the concentrated hydrofluoric acid to the water ranges from about 1:500 to about 1:5000. In some embodiments, the wet clean process may be conducted using a single wafer type equipment or a batch type equipment. In some embodiments, the wet clean process may be conducted at a temperature ranging from about 5° C. to about 50° C. In some embodiments, the wet clean process may be conducted for a time period ranging from about 10 seconds to about 360 seconds.

In some embodiments, the first self-assembled monolayer 61 is formed by applying first precursor molecules into the first cavity 31. Each of the first precursor molecules has a first head group and a first tail group opposite to the first head group. The first head group has an affinity to the first functional groups which is higher than an affinity to the second functional groups. Hence, the first self-assembled monolayer 61 may be selectively formed on the first surface Si through a reaction between the first head group and the first functional groups. On the other hand, due to a low reactivity of the first head group with the second functional groups, in some embodiments, the first self-assembled monolayer 61 is less likely to be formed on the second surfaces S2, and thus the two second surfaces S2 are exposed from the first self-assembled monolayer 61. In some other embodiments not shown herein, the second surfaces S2 may further include the first functional group in a relatively small amount such that although the first self-assembled monolayer 61 may be partially formed on the second surfaces S2, at least a majority of the two second surfaces S2 is exposed from the first self-assembled monolayer 61.

In some embodiments, the first precursor molecules include a substituted silane. In some embodiments, the first head group may be —SiH₂NH₂, —Si(CH₃)₂NH₂, —Si(CH₃)₂N(CH₃)₂, or —SiR₃, where R is selected from F, Cl, Br, CH₃, OCH₃, or OC₂H₅. In some embodiments, the first tail group is a linear alkyl group of CH₃(CH₂)ₚ—, where p is an integer ranging from 0 to 20, or a linear halo-substituted alkyl group of CA₃(CA₂)ₙ(CH₂)ₘ, where A is selected from F, Cl, or Br, n is an integer ranging from 0 to 10, and m is an integer ranging from 0 to 10. For example, the first precursor molecules may be selected from hexamethyldisilazane (HMDS, which is represented by a chemical formula of (CH₃)₃SiNHSi(CH₃)₃), (dimethylamino)trimethylsilane (DMA-TMS, which is represented by a chemical formula of (CH₃)₃SiN(CH₃)₂), octadecyltrichlorosilane (ODTS, which is represented by a chemical formula of CH₃(CH₂)₁₇SiCl₃), other suitable precursor molecules, or combinations thereof.

In some embodiments, the first self-assembled monolayer 61 is obtained by reacting the first precursor molecules with the first functional groups (see FIG. 9), and is formed with the first tail group which is different from the second functional groups. For example, the first self-assembled monolayer 61 exemplarily shown in FIG. 12 is obtained by reacting ODTS with the first functional groups, and is formed with a linear alkyl group of CH₃(CH₂)₁₇—. Furthermore, in some embodiments, the first self-assembled monolayer 61 is formed on the first surface Si via a Si—O bond. Other chemical structures suitable for the first self-assembled monolayer 61, which are not shown in FIG. 12 and which are obtained by reacting other first precursor molecules with the first functional groups, are also within the contemplated scope of the present disclosure.

In some embodiments, in step S07, a first solution, which includes the first precursor molecules and a first solvent, is applied into the first cavity 31. Examples of the first solvent are not limited as long as the first precursor molecules can be dissolved therein. In some embodiments, the first solvent includes propylene glycol monomethyl ether acetate (PGMEA), acetone, benzene, ethyl ether, heptane, perchloroethylene, di(methylsulfonyl)ethane (DMSE, C₄H₁₀O₄S₂), ethyl acetate, other suitable solvents, or combinations thereof. In some embodiments, formation of the first self-assembled monolayer 61 may be conducted using a single wafer type equipment or a batch type equipment. In some embodiments, formation of the first self-assembled monolayer 61 may be conducted at a temperature ranging from about 5° C. to about 70° C.

In some embodiments, after step S07, another first self-assembled monolayer (not shown, similar to the first self-assembled monolayer 61) is further selectively formed on the exposed surface of each of the interfacial layers 331, 332, 333, 334 (see FIG. 7), which borders the corresponding second cavity 32, while leaving the exposed surface of each of the inner spacers 25 (see FIG. 7) exposed from the another first self-assembled monolayer.

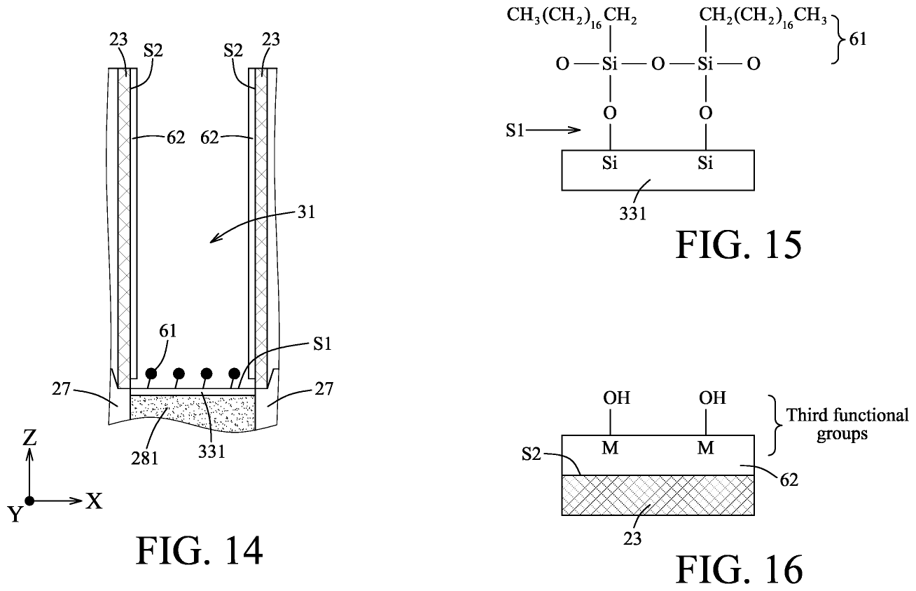

Referring to FIG. 1 and the examples illustrated in FIGS. 14 to 16, the method 10 proceeds to step S08, where two dummy layers 62 are selectively formed on the two second surfaces S2 of the two gate spacers 23, respectively, while leaving the first self-assembled monolayer 61 exposed from the two dummy layers 62. FIGS. 14 to 16 are views similar to those of FIGS. 11 to 13, but illustrating the structures after step S08. In some embodiments, as shown in FIG. 15, the functional groups on the first surface S1 after step S08 are the same as those shown in FIG. 12 without being changed.

The two dummy layers 62 are made of a material different from a material of the two gate spacers 23, and are formed with third functional groups that are different from the first functional groups (see FIG. 18) and the second functional groups. In some embodiments, the dummy layers 62 include metal oxide, such as aluminum oxide, titanium oxide, or a combination thereof. Other metal oxide materials suitable for forming the two dummy layers 62 are within the contemplated scope of the present disclosure. In some embodiments, the third functional groups include M-OH groups, where M is metal. In some embodiments, M is aluminum, titanium, or other suitable metal elements. In some embodiments, the two dummy layers 62 are formed by CVD, ALD, PVD, or other suitable deposition techniques. In some embodiments, formation of the two dummy layers 62 includes applying a first material precursor into the first cavity 31. Since the first material precursor is selected to have an affinity to the second functional groups (see FIG. 13) which is higher than an affinity to the first tail group (e.g., CH₃(CH₂)₁₇— exemplarily shown in FIG. 12), so that the two dummy layers 62 are capable to be selectively formed on the two second surfaces S2, respectively through a reaction between the first material precursor and the second functional groups. Since the first surface S1 is passivated by the first tail group, the metal oxide of the dummy layers 62 is prevented from being formed on the first surface Si.

In some embodiments, in the case that the dummy layers 62 are made of aluminum oxide, the dummy layers 62 may be formed by ALD using trimethylaluminum and water as the first material precursor at a temperature ranging from about 100° C. to about 500° C. under a pressure ranging from about 50 mTorr to about 5000 mTorr. In some embodiments, in the case that the dummy layers 62 are made of titanium oxide, the dummy layers 62 may be formed by ALD using titanium tetrachloride and water as the first material precursor at a temperature ranging from about 100° C. to about 500° C. under a pressure ranging from about 50 mTorr to about 5000 mTorr.

In some embodiments, another dummy layer (not shown, similar to the dummy layers 62) is selectively formed on the exposed surface of each of the inner spacers 25, while leaving the another first self-assembled monolayer exposed from the another dummy layer.

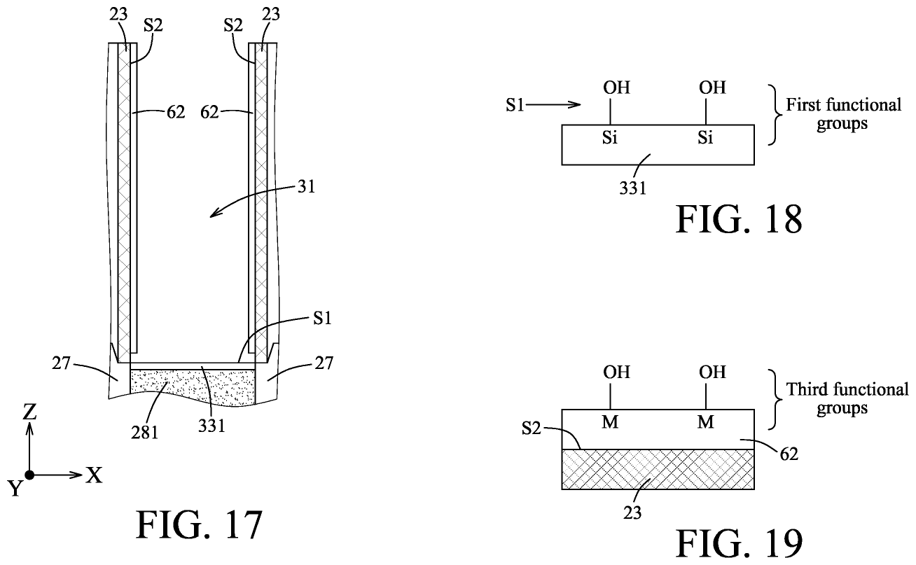

Referring to FIG. 1 and the examples illustrated in FIGS. 17 to 19, the method 10 proceeds to step S09, where the first self-assembled monolayer 61 (see FIGS. 14 and 15) is removed to expose the first surface S1 of the interfacial layer 331. FIGS. 17 to 19 are views similar to those of FIGS. 14 to 16, but illustrating the structures after step S09. In some embodiments, as shown in FIG. 19, the functional groups on each second surface S2 after step S09 are the same as those shown in FIG. 16 without being changed.

In some embodiments, the first self-assembled monolayer 61 may be removed by an ashing process using a plasma. In some embodiments, the plasma may be an oxygen plasma which is generated from an oxygen gas by applying a power ranging from about 50 W to about 1000 W. In some embodiments, the ashing process using the oxygen plasma may be conducted at room temperature under a pressure ranging from about 0 Pa to about 100 Pa. In some embodiments, the plasma may be a mixture of hydrogen plasma and nitrogen plasma which is generated from a mixture of hydrogen gas and nitrogen gas. In some embodiments, the mixture of hydrogen gas and nitrogen gas may be introduced in a flow rate ranging from about 100 sccm to about 1000 sccm. In some embodiments, the ashing process using the mixture of hydrogen plasma and nitrogen plasma may be conducted at room temperature under a pressure ranging from about 1 Torr to about 100 Torr. In some embodiments, the first self-assembled monolayer 61 may be removed by an ultraviolet-ozone (UV—O₃) treatment process. In some embodiments, a wavelength of the UV light may range from about 100 nm to about 260 nm. In some embodiments, a light power of the UV light may range from about 20 mW/cm² to about 40 mW/cm². In some embodiments, the UV—O₃ treatment process may be conducted at room temperature. In some embodiments, the first self-assembled monolayer 61 may be removed by a thermal treatment process at a temperature ranging from about 300° C. to about 800° C. for a time period ranging from about 1 minute to about 120 minutes. In some embodiments, the thermal treatment process may be conducted in the presence of air or in an inert environment including nitrogen gas, argon or other suitable inert gases. It is noted that process parameters (e.g., temperature, pressure, process time, or other process parameters as mentioned above) are not limited to the above value, and may be fine-tuned so as to ensure that the first self-assembled monolayer 61 is completely removed. Other processes suitable for removing the first self-assembled monolayer 61 are within the contemplated scope of the present disclosure.

Referring to FIG. 18, after removing the first self-assembled monolayer 61, the first surface Si, which is formed with the first functional groups, is thus exposed to the first cavity 31 (see FIG. 17). In some embodiments, the another first self-assembled monolayer (not shown) is removed together with the first self-assembled monolayer 61, so that the exposed surface of each of the interfacial layers 331, 332, 333, 334 (see FIG. 7), which borders the corresponding second cavity 32, is thus exposed to the second cavity 32.

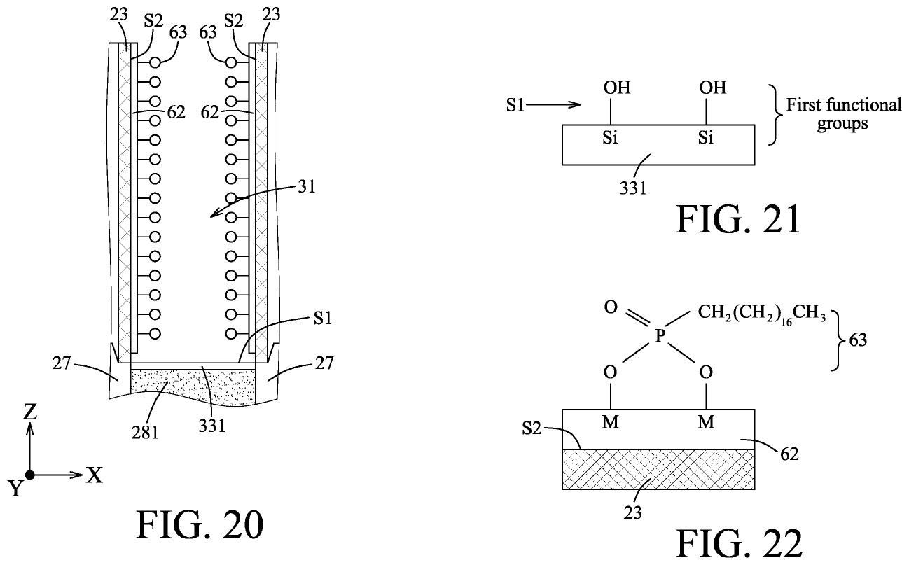

Referring to FIG. 1 and the examples illustrated in FIGS. 20 to 22, the method 10 proceeds to step S10, where two second self-assembled monolayers 63 are respectively formed on the two dummy layers 62, while leaving the first surface Si of the interfacial layer 331 exposed from the two second self-assembled monolayers 63. FIGS. 20 to 22 are views similar to those of FIGS. 17 to 19, but illustrating the structures after step S10. In some embodiments, as shown in FIG. 21, the functional groups on the first surface S1 after step S10 are the same as those shown in FIG. 18 without being changed.

In some embodiments, the second self-assembled monolayers 63 are formed by applying second precursor molecules into the first cavity 31. Each of the second precursor molecules has a second head group and a second tail group opposite to the second head group. The second head group has an affinity to the third functional groups (see FIG. 19) which is higher than an affinity to the first functional groups. Hence, the second self-assembled monolayer 63 may be selectively formed on each second surface S2 through a reaction between the second head group and the third functional groups. On the other hand, due to a low reactivity of second first head group with the first functional groups, the second self-assembled monolayer 63 is less likely to form on the first surface S1, and thus the first surface S1 is exposed from the second self-assembled monolayer 63.

In some embodiments, the second head group includes —PO(OH)₂. In some embodiments, the second tail group is a linear alkyl group of CH₃(CH₂)_{q}—, wherein q is an integer ranging from 0 to 20; a linear halo-substituted alkyl group of CE₃(CE₂)ᵣ(CH₂)ₛ—, wherein E is selected from F, Cl, or Br, r is an integer ranging from 0 to 10, and s is an integer ranging from 0 to 10; or a group of G-O—(CH₂)ₜ—, where G is an aryl radical or a halo-substituted aryl radical, and t is an integer ranging from 0 to 10. In some embodiments, G is fluoro-substituted phenyl. For example, the second precursor molecules may be selected from octadecylphosphonic acid (ODPA, which is represented by a chemical formula of CH₃(CH₂)₁₇PO(OH)₂), 1H,1H,2H,2H-perfluorododecyl phosphonic acid (PFDPA, which is represented by a chemical formula of CF₃(CF₂)₉(CH₂)₂PO(OH)₂), dodecylphosphonic acid (DPA, which is represented by a chemical formula of CH₃(CH₂)₁₁PO(OH)₂), octylphosphonic acid (OPA, which is represented by a chemical formula of CH₃(CH₂)₇PO(OH)₂), 12-pentafluorophenoxydodecylphosphonic acid (PFPDPA, which is represented by a chemical formula of (C₆F₅)O(CH₂)₁₂PO(OH)₂), other suitable precursor molecules, or combinations thereof.

In some embodiments, the second self-assembled monolayer 63 is obtained by reacting the second precursor molecules with the third functional groups (see FIG. 16), and is formed with the second tail group which is different from the first functional groups. For example, the second self-assembled monolayer 63 exemplarily shown in FIG. 22 is obtained by reacting ODPA with the third functional groups, and is formed with a linear alkyl group of CH₃(CH₂)₁₇—. Furthermore, in some embodiments, the second self-assembled monolayer 63 is formed on each dummy layer 62 via at least one P—O bond. Other chemical structures suitable for the second self-assembled monolayer 63, which are not shown in FIG. 22, obtained by reacting other second precursor molecules with the third functional groups are also within the contemplated scope of the present disclosure.

In some embodiments, in step S10, a second solution, which includes the second precursor molecules and a second solvent, is applied to the first cavity 31. Examples of the second solvent are not limited as long as the second precursor molecules can be dissolved therein. In some embodiments, the second solvent includes propylene glycol monomethyl ether acetate (PGMEA), acetone, benzene, ethyl ether, heptane, perchloroethylene, di(methylsulfonyl)ethane (DMSE, C₂₅H₂₉NO₁₀S), ethyl acetate, other suitable solvents, or combinations thereof. In some embodiments, formation of the second self-assembled monolayer 63 may be conducted using a single wafer type equipment or a batch type equipment. In some embodiments, formation of the second self-assembled monolayer 63 may be conducted at a temperature ranging from about 5° C. to about 150° C.

In some embodiments, after step S10, another second self-assembled monolayer (not shown, similar to the second self-assembled monolayer 63) is further selectively formed on the another dummy layer (not shown), while leaving the exposed surface of each of the interfacial layers 331, 332, 333, 334 (see FIG. 7), which borders the corresponding second cavity 32, exposed from the another second self-assembled monolayer.

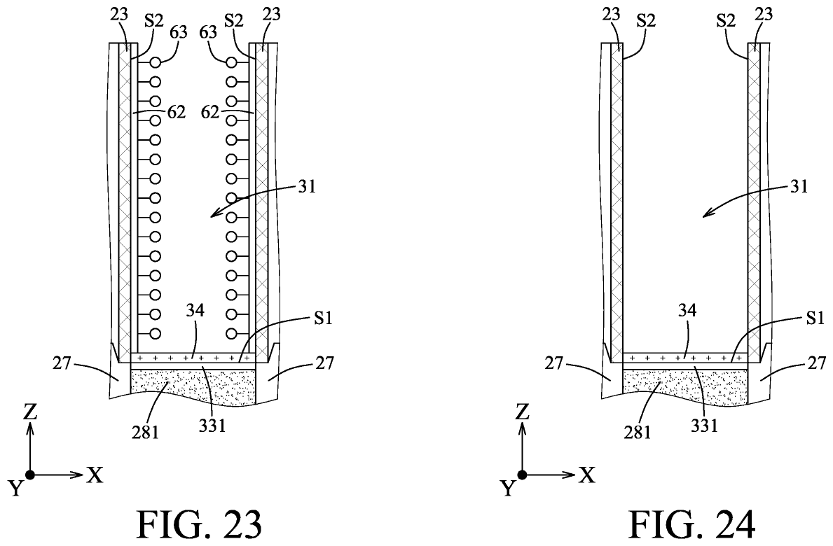

Referring to FIG. 1 and the example illustrated in FIG. 23, the method 10 proceeds to step S11, where a gate dielectric layer 34 is formed on the first surface Si of the interfacial layer 331 while leaving the two second self-assembled monolayers 63 exposed from the gate dielectric layer 34. FIG. 23 is a view similar to that of FIG. 20, but illustrating the structure after step S11.

In some embodiments, the gate dielectric layer 34 includes silicon oxide, silicon nitride, silicon oxynitride, a suitable high-k material (such as hafnium oxide, zirconium oxide, zirconium aluminum oxide, hafnium aluminum oxide, hafnium silicon oxide, aluminum oxide, etc.), other suitable materials, or combinations thereof. Other dielectric materials suitable for the gate dielectric layer 34 are within the contemplated scope of the present disclosure. In some embodiments, the gate dielectric layer 34 may be formed by CVD, ALD, PVD, or other suitable deposition techniques. In some embodiments, formation of the gate dielectric layer 34 includes applying a second material precursor into the first cavity 31. Since the second material precursor is selected to have an affinity to the first functional groups (see FIG. 21) which is higher than an affinity to the second tail group (e.g., CH₃(CH₂)₁₇— exemplarily shown in FIG. 22), so that the gate dielectric layer 34 is capable to be selectively formed on the first surface Si through a reaction between the second material precursor and the first functional groups. Since the two second surfaces S2 are passivated by the second tail group, the gate dielectric layer 34 is prevented from being formed on the two second surfaces S2.

In some embodiments, in the case that the gate dielectric layer 34 is made of hafnium oxide, the gate dielectric layer 34 may be formed by ALD using a hafnium-containing precursor and water as the second material precursor at a temperature ranging from about 100° C. to about 500° C. under a pressure ranging from about 50 mTorr to about 5000 mTorr. In some embodiments, the hafnium-containing precursor includes hafnium tetrachloride, tetrakis(dimethylamido)hafnium (TDMAHf), tetrakis(ethylmethylamido)hafnium (TEMAHf), other suitable metal-organic compounds including hafnium, or combinations thereof.

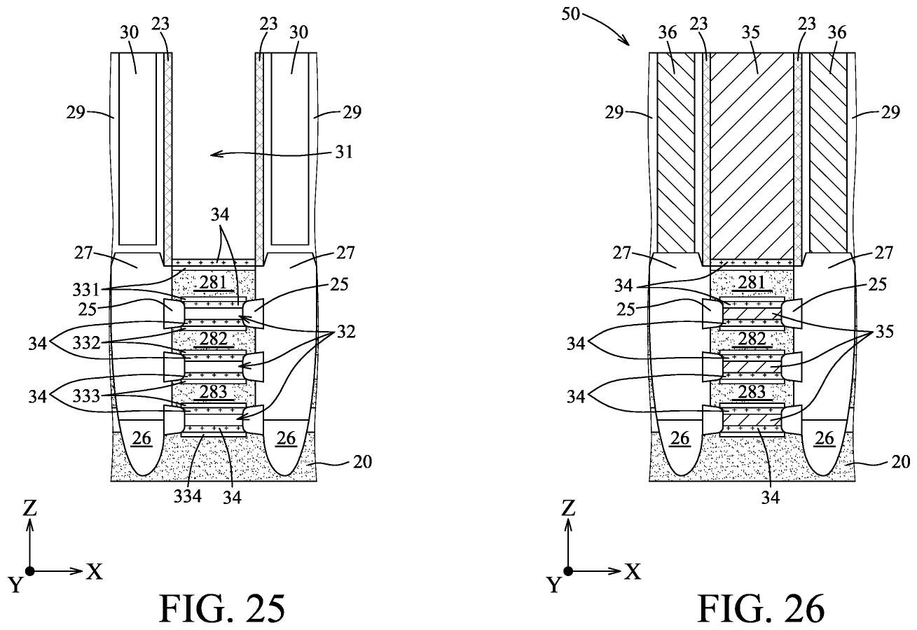

In some embodiments, after step S11, the gate dielectric layer 34 (see FIG. 25) is further selectively formed on the exposed surface of each of the interfacial layers 331, 332, 333, 334, which borders the corresponding second cavity 32, while leaving the exposed surface of each of the inner spacers 25 exposed from the gate dielectric layer 34.

Referring to FIG. 1 and the examples illustrated in FIGS. 24 and 25, the method 10 proceeds to step S12, where the two second self-assembled monolayers 63 and the two dummy layers 62 (see FIG. 23) are removed to expose the two second surfaces S2 of the gate spacers 23. FIG. 24 is a view similar to that of FIG. 23, but illustrating the structure after step S12. FIG. 25 is a view similar to that of FIG. 7, but illustrating structure after step S12 and illustrating the other elements omitted in FIG. 24.

In some embodiments, a wet etching process may be utilized to remove the dummy layers 62. In the wet etching process, a wet etchant used therein has a higher etching selectivity (or higher etching rate) over the dummy layers 62 than the interfacial layer 331 and the gate spacers 23 so that the interfacial layer 331 and the gate spacers 23 are substantially not removed. When the dummy layers 62 are removed by the wet etching process, the second self-assembled monolayers 63 respectively formed on the dummy layers 62 are removed simultaneously. In some embodiments, the wet etching process may be conducted using a single wafer type equipment or a batch type equipment. In some embodiments, the wet etching process may be conducted at a temperature ranging from about room temperature to about 70° C. In some embodiments, the wet etching process may be conducted for a time period ranging from about 10 seconds to about 360 seconds.

In some embodiments, in the case that the dummy layers 62 are made of titanium oxide, the wet etchant may include water (solvent) and a mixture of NH₄OH and H₂O₂ dissolved therein. In some embodiments, a volumetric ratio of NH₄OH to H₂O₂ to H₂O ranges from about 1:1:1 to about 1:1:100. In some embodiments, in the case that the dummy layers 62 are made of aluminum oxide, the wet etchant may include water (solvent) and NH₄OH dissolved therein. In some embodiments, a volumetric ratio of NH₄OH to H₂O ranges from about 1:5 to about 1:250. Other chemical solutions suitable for removing the dummy layers 62 are within the contemplated scope of the present disclosure. In some embodiments, parameter(s) of the wet etching process (e.g., temperature and concentration of the wet etchant, and so on) can be adjusted so that the dummy layers 62 can be selectively removed completely.

In some embodiments, after step S12, the another dummy layer and the another second self-assembled monolayer (not shown) are removed together with the dummy layers 62 and the second self-assembled monolayers 63 (see FIG. 23), so that the expose surface of each of the inner spacers 25 is thus exposed to the second cavity 32.

Referring to FIG. 1 and the example illustrated in FIG. 26, the method 10 proceeds to step S13, where a gate electrode 35 is formed to fill the first and second cavities 31, 32 (see FIG. 25), and then two source/drain contacts 36 are respectively formed in the ILD layers 30 (see FIG. 25) to be respectively connected to the two source/drain regions 27, thereby obtaining the semiconductor structure 50. FIG. 26 is a view similar to that of FIG. 25, but illustrating the structure after step S13.

In some embodiments, the gate electrode 35 may include a work-function material which is provided for adjusting threshold voltage of an n-FET or a p-FET, and an electrically conductive material which has a low resistance and which is provided for reducing overall electrical resistance of the gate electrode 35. In some embodiments, the work-function material may include, for example, but not limited to, titanium, aluminum, tantalum carbide, tantalum carbide nitride, tantalum silicon nitride, or combinations thereof. In some embodiments, the electrically conductive material may include, for example, but not limited to, tungsten, cobalt, ruthenium, iridium, alloy thereof, or combinations thereof. In some embodiments, the source/drain contacts 36 may include, for example, but not limited to, cobalt, ruthenium, tungsten, molybdenum, alloys thereof, or combinations thereof. Other materials suitable for the gate electrode 35 and the source/drain contacts 36 are within the contemplated scope of the present disclosure.

In some embodiments, the semiconductor structure 50 may further include additional features, and/or some features present in the semiconductor structure 50 may be modified, replaced, or eliminated without departure from the spirit and scope of the present disclosure. In some embodiments, some steps in the method 10 may be modified, replaced, or eliminated without departure from the spirit and scope of the present disclosure.

In summary, by utilizing the first self-assembled monolayer 61 that is selectively formed on the interfacial layer 331, the dummy layers 62 and the second self-assembled monolayers 63 may be sequentially formed on the gate spacers 23 without being formed on the interfacial layer 331 which is passivated by the first self-assembled monolayer 61. After removal of the first self-assembled monolayer 61, by utilizing precursor molecules which have an affinity to the interfacial layer 331 which is larger than an affinity to the second self-assembled monolayers 63, a selective deposition of the gate dielectric layer 34 on the interfacial layer 331 without being performed on the gate spacers 23 (which are respectively passivated by the second self-assembled monolayers 63) may be achieved. As a result, a parasitic capacitance formed between the gate electrode 35 and one of the source/drain contacts 36 may be significantly reduced due to the absence of the gate dielectric layer 34 between the gate electrode 35 and the one of the source/drain contacts 36.

In accordance with some embodiments of the present disclosure, a method for manufacturing a semiconductor structure includes: forming a patterned structure including an interfacial layer and two dielectric spacers at two opposite sides of the interfacial layer, a first surface of the interfacial layer and two second surfaces of the two dielectric spacers being arranged to border a cavity, the first surface being formed with first functional groups, the two second surfaces being formed with second functional groups that are different from the first functional groups; selectively forming a first self-assembled monolayer on the first surface of the interfacial layer while leaving the two second surfaces of the two dielectric spacers exposed from the first self-assembled monolayer; after selectively forming the first self-assembled monolayer, selectively forming two dummy layers respectively on the two second surfaces of the two dielectric spacers while leaving the first self-assembled monolayer exposed from the two dummy layers, the two dummy layers being made of a material different from a material of the two dielectric spacers; after selectively forming the two dummy layers, removing the first self-assembled monolayer to expose the first surface of the interfacial layer; selectively forming two second self-assembled monolayers respectively on the two dummy layers while leaving the first surface of the interfacial layer exposed from the two second self-assembled monolayers; and after selectively forming the two second self-assembled monolayers, selectively forming a gate dielectric layer on the first surface of the interfacial layer while leaving the two second self-assembled monolayers exposed from the gate dielectric layer.

In accordance with some embodiments of the present disclosure, the method further includes, after selectively forming the gate dielectric layer, removing the two second self-assembled monolayers and the two dummy layers to expose the two second surfaces of the two dielectric spacers.

In accordance with some embodiments of the present disclosure, the method further includes, before selectively forming the first self-assembled monolayer, performing a pretreatment process on the two dielectric spacers such that the second functional groups formed on the second surfaces of the two dielectric spacers are exposed.

In accordance with some embodiments of the present disclosure, the first self-assembled monolayer is formed by applying first precursor molecules into the cavity. Each of the first precursor molecules has a first head group and a first tail group opposite to the first head group. The first head group has an affinity to the first functional groups which is higher than an affinity to the second functional groups. The first tail group is different from the second functional groups.

In accordance with some embodiments of the present disclosure, the first functional groups include hydroxyl groups, and the second functional groups include amino groups of —NHₓ, where x is 1 or 2.

In accordance with some embodiments of the present disclosure, the first head group includes —SiH₂NH₂, —Si(CH₃)₂NH₂, —Si(CH₃)₂N(CH₃)₂, or —SiR₃, where R is selected from F, Cl, Br, CH₃, OCH₃, or OC₂H₅.

In accordance with some embodiments of the present disclosure, the first self-assembled monolayer is formed with the first tail group, and a material precursor for forming the two dummy layers has an affinity to the second functional groups which is higher than an affinity to the first tail group.

In accordance with some embodiments of the present disclosure, the first tail group is a linear alkyl group of CH₃(CH₂)ₚ—, wherein p is an integer ranging from 0 to 20; or a linear halo-substituted alkyl group of CA₃(CA₂)ₙ(CH₂)ₘ—, wherein A is selected from F, Cl, or Br, n is an integer ranging from 0 to 10, and m is an integer ranging from 0 to 10.

In accordance with some embodiments of the present disclosure, the two second self-assembled monolayers are formed by applying second precursor molecules into the cavity. Each of the second precursor molecules having a second head group and a second tail group opposite to the second head group. The second head group has an affinity to the two dummy layers which is higher than an affinity to the first functional groups. The second tail group is different from the first functional groups.

In accordance with some embodiments of the present disclosure, the second head group includes —PO(OH)₂.

In accordance with some embodiments of the present disclosure, the second tail group is a linear alkyl group of CH₃(CH₂)_{q}—, wherein q is an integer ranging from 0 to 20; a linear halo-substituted alkyl group of CE₃(CE₂)ᵣ(CH₂)ₛ—, wherein E is selected from F, Cl, or Br, r is an integer ranging from 0 to 10, and s is an integer ranging from 0 to 10; or a group of G-O—(CH₂)ₜ—, where G is an aryl radical or a halo-substituted aryl radical, and t is an integer ranging from 0 to 10.

In accordance with some embodiments of the present disclosure, a method for manufacturing a semiconductor structure includes: forming a patterned structure including an interfacial layer and two dielectric spacers at two opposite sides of the interfacial layer, a first surface of the interfacial layer and two second surfaces of the two dielectric spacers being arranged to border a cavity, the first surface being formed with first functional groups, the two second surfaces being formed with second functional groups that are different from the first functional groups; selectively forming two metal oxide layers respectively on the second surfaces of the two dielectric spacers while leaving the first surface of the interfacial layer exposed from the two metal oxide layers, the two metal oxide layers being formed with third functional groups that are different from the first functional groups and the second functional groups; applying precursor molecules to the cavity, the precursor molecules having an affinity to the third functional groups which is higher than an affinity to the first functional groups so that two self-assembled monolayers are respectively and selectively formed on the two metal oxide layers while leaving the first surface of the interfacial layer exposed from the two self-assembled monolayers; and after selectively forming the two self-assembled monolayers, selectively forming a gate dielectric layer on the first surface of the interfacial layer while leaving the two self-assembled monolayers exposed from the gate dielectric layer.

In accordance with some embodiments of the present disclosure, the first functional groups include hydroxyl groups, and the second functional groups include amino groups of —NH₂.

In accordance with some embodiments of the present disclosure, the third functional groups include M-OH groups, where M is metal, and the interfacial layer includes silicon oxide, the first functional groups including Si—OH groups.

In accordance with some embodiments of the present disclosure, each of the two metal oxide layers includes aluminum oxide, titanium oxide, or a combination thereof.

In accordance with some embodiments of the present disclosure, each of the precursor molecules has a head group and a tail group opposite to the head group. The head group has an affinity to the two metal oxide layers which is higher than an affinity to the first functional groups. The tail group is different from the first functional groups. A dielectric precursor for forming the gate dielectric layer has an affinity to the first functional groups which is higher than an affinity to the tail group of each of the precursor molecules.

In accordance with some embodiments of the present disclosure, the head group is —PO(OH)₂. The tail group is a linear alkyl group of CH₃(CH₂)_{q}—, wherein q is an integer ranging from 0 to 20; a linear halo-substituted alkyl group of CE₃(CE₂)ᵣ(CH₂)ₛ—, wherein E is selected from F, Cl, or Br, r is an integer ranging from 0 to 10, and s is an integer ranging from 0 to 10; or a group of G-O—(CH₂)ₜ—, where G is an aryl radical or a halo-substituted aryl radical, and t is an integer ranging from 0 to 10.

In accordance with some embodiments of the present disclosure, G is fluoro-substituted phenyl.

In accordance with some embodiments of the present disclosure, a method for manufacturing a semiconductor structure includes: forming a patterned structure having a first surface formed with first functional groups and a second surface formed with second functional groups that are different from the first functional groups; applying first precursor molecules to the first surface and the second surface, the first precursor molecules having an affinity to the first functional groups which is higher than an affinity to the second functional groups so that a first self-assembled monolayer is selectively formed on the first surface while leaving the second surface exposed from the first self-assembled monolayer; after selectively forming the first self-assembled monolayer, selectively forming a dummy layer on the second surface while leaving the first self-assembled monolayer exposed from the dummy layer, the dummy layer being formed with third functional groups that are different from the first functional groups and the second functional groups; after selectively forming the dummy layer, removing the first self-assembled monolayer to expose the first surface; applying second precursor molecules to the first surface and the dummy layer, the second precursor molecules having an affinity to the third functional groups which is higher than an affinity to the first functional groups so that a second self-assembled monolayer is selectively formed on the dummy layer while leaving the first surface exposed from the second self-assembled monolayer; and after selectively forming the second self-assembled monolayer, selectively forming a dielectric layer on the first surface while leaving the second self-assembled monolayer exposed from the dielectric layer.

In accordance with some embodiments of the present disclosure, the first functional groups include Si—OH groups, the second functional groups include Si—NHₓ groups, where x is 1 or 2, the third functional groups including M-OH groups, where M is metal, the first precursor molecules include hexamethyldisilazane, (dimethylamino)trimethylsilane, octadecyltrichlorosilane, or combinations thereof, and the second precursor molecules include dodecylphosphonic acid, octylphosphonic acid, 12-pentafluorophenoxydodecylphosphonic acid, 1H,1H,2H,2H-perfluorododecyl phosphonic acid, octadecylphosphonic acid, or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a patterned structure including an interfacial layer and two dielectric spacers at two opposite sides of the interfacial layer, a first surface of the interfacial layer and two second surfaces of the two dielectric spacers being arranged to border a cavity, the first surface being formed with first functional groups, the two second surfaces being formed with second functional groups that are different from the first functional groups;
selectively forming a first self-assembled monolayer on the first surface of the interfacial layer while leaving the two second surfaces of the two dielectric spacers exposed from the first self-assembled monolayer;
after selectively forming the first self-assembled monolayer, selectively forming two dummy layers respectively on the two second surfaces of the two dielectric spacers while leaving the first self-assembled monolayer exposed from the two dummy layers, the two dummy layers being made of a material different from a material of the two dielectric spacers;
after selectively forming the two dummy layers, removing the first self-assembled monolayer to expose the first surface of the interfacial layer;
selectively forming two second self-assembled monolayers respectively on the two dummy layers while leaving the first surface of the interfacial layer exposed from the two second self-assembled monolayers; and
after selectively forming the two second self-assembled monolayers, selectively forming a gate dielectric layer on the first surface of the interfacial layer while leaving the two second self-assembled monolayers exposed from the gate dielectric layer.

2. The method as claimed in claim 1, further comprising, after selectively forming the gate dielectric layer, removing the two second self-assembled monolayers and the two dummy layers to expose the two second surfaces of the two dielectric spacers.

3. The method as claimed in claim 1, further comprising, before selectively forming the first self-assembled monolayer, performing a pretreatment process on the two dielectric spacers such that the second functional groups formed on the second surfaces of the two dielectric spacers are exposed.

4. The method as claimed in claim 1, wherein the first self-assembled monolayer is formed by applying first precursor molecules into the cavity, each of the first precursor molecules having a first head group and a first tail group opposite to the first head group, the first head group having an affinity to the first functional groups which is higher than an affinity to the second functional groups, the first tail group being different from the second functional groups.

5. The method as claimed in claim 4, wherein the first functional groups include hydroxyl groups, and the second functional groups include amino groups of —NHₓ, where x is 1 or 2.

6. The method as claimed in claim 4, wherein the first head group includes —SiH₂NH₂, —Si(CH₃)₂NH₂, —Si(CH₃)₂N(CH₃)₂, or —SiR₃, where R is selected from F, Cl, Br, CH₃, OCH₃, or OC₂H₅.

7. The method as claimed in claim 4, wherein
the first self-assembled monolayer is formed with the first tail group, and
a material precursor for forming the two dummy layers has an affinity to the second functional groups which is higher than an affinity to the first tail group.

8. The method as claimed in claim 7, wherein the first tail group is
a linear alkyl group of CH₃(CH₂)ₚ—, wherein p is an integer ranging from 0 to 20; or
a linear halo-substituted alkyl group of CA₃(CA₂)ₙ(CH₂)ₘ—, wherein A is selected from F, Cl, or Br, n is an integer ranging from 0 to 10, and m is an integer ranging from 0 to 10.

9. The method as claimed in claim 1, wherein the two second self-assembled monolayers are formed by applying second precursor molecules into the cavity, each of the second precursor molecules having a second head group and a second tail group opposite to the second head group, the second head group having an affinity to the two dummy layers which is higher than an affinity to the first functional groups, the second tail group being different from the first functional groups.

10. The method as claimed in claim 9, wherein the second head group includes —PO(OH)₂.

11. The method as claimed in claim 9, wherein the second tail group is
a linear alkyl group of CH₃(CH₂)_{q}—, wherein q is an integer ranging from 0 to 20;
a linear halo-substituted alkyl group of CE₃(CE₂)ᵣ(CH₂)ₛ—, wherein E is selected from F, Cl, or Br, r is an integer ranging from 0 to 10, and s is an integer ranging from 0 to 10; or
a group of G-O—(CH₂)ₜ—, where G is an aryl radical or a halo-substituted aryl radical, and t is an integer ranging from 0 to 10.

12. A method for manufacturing a semiconductor structure, comprising:
forming a patterned structure including an interfacial layer and two dielectric spacers at two opposite sides of the interfacial layer, a first surface of the interfacial layer and two second surfaces of the two dielectric spacers being arranged to border a cavity, the first surface being formed with first functional groups, the two second surfaces being formed with second functional groups that are different from the first functional groups;
selectively forming two metal oxide layers respectively on the second surfaces of the two dielectric spacers while leaving the first surface of the interfacial layer exposed from the two metal oxide layers, the two metal oxide layers being formed with third functional groups that are different from the first functional groups and the second functional groups;
applying precursor molecules to the cavity, the precursor molecules having an affinity to the third functional groups which is higher than an affinity to the first functional groups so that two self-assembled monolayers are respectively and selectively formed on the two metal oxide layers while leaving the first surface of the interfacial layer exposed from the two self-assembled monolayers; and
after selectively forming the two self-assembled monolayers, selectively forming a gate dielectric layer on the first surface of the interfacial layer while leaving the two self-assembled monolayers exposed from the gate dielectric layer.

13. The method as claimed in claim 12, wherein the first functional groups include hydroxyl groups, and the second functional groups include amino groups of —NH₂.

14. The method as claimed in claim 13, wherein
the third functional groups include M-OH groups, where M is metal, and
the interfacial layer includes silicon oxide, the first functional groups including Si—OH groups.

15. The method as claimed in claim 12, wherein each of the two metal oxide layers includes aluminum oxide, titanium oxide, or a combination thereof.

16. The method as claimed in claim 12, wherein
each of the precursor molecules has a head group and a tail group opposite to the head group, the head group having an affinity to the two metal oxide layers which is higher than an affinity to the first functional groups, the tail group being different from the first functional groups, and
a dielectric precursor for forming the gate dielectric layer has an affinity to the first functional groups which is higher than an affinity to the tail group of each of the precursor molecules.

17. The method as claimed in claim 15, wherein
the head group is —PO(OH)₂, and
the tail group is a linear alkyl group of CH₃(CH₂)_{q}—, wherein q is an integer ranging from 0 to 20; a linear halo-substituted alkyl group of CE₃(CE₂)ᵣ(CH₂)ₛ—, wherein E is selected from F, Cl, or Br, r is an integer ranging from 0 to 10, and s is an integer ranging from 0 to 10; or a group of G-O—(CH₂)ₜ—, where G is an aryl radical or a halo-substituted aryl radical, and t is an integer ranging from 0 to 10.

18. The method as claimed in claim 17, wherein G is fluoro-substituted phenyl.

19. A method for manufacturing a semiconductor structure, comprising:
forming a patterned structure having a first surface formed with first functional groups and a second surface formed with second functional groups that are different from the first functional groups;
applying first precursor molecules to the first surface and the second surface, the first precursor molecules having an affinity to the first functional groups which is higher than an affinity to the second functional groups so that a first self-assembled monolayer is selectively formed on the first surface while leaving the second surface exposed from the first self-assembled monolayer;
after selectively forming the first self-assembled monolayer, selectively forming a dummy layer on the second surface while leaving the first self-assembled monolayer exposed from the dummy layer, the dummy layer being formed with third functional groups that are different from the first functional groups and the second functional groups;
after selectively forming the dummy layer, removing the first self-assembled monolayer to expose the first surface;
applying second precursor molecules to the first surface and the dummy layer, the second precursor molecules having an affinity to the third functional groups which is higher than an affinity to the first functional groups so that a second self-assembled monolayer is selectively formed on the dummy layer while leaving the first surface exposed from the second self-assembled monolayer; and
after selectively forming the second self-assembled monolayer, selectively forming a dielectric layer on the first surface while leaving the second self-assembled monolayer exposed from the dielectric layer.

20. The method as claimed in claim 19, wherein
the first functional groups include Si—OH groups,
the second functional groups include Si—NHₓ groups, where x is 1 or 2,
the third functional groups including M—OH groups, where M is metal,
the first precursor molecules include hexamethyldisilazane, (dimethylamino)trimethylsilane, octadecyltrichlorosilane, or combinations thereof, and
the second precursor molecules include dodecylphosphonic acid, octylphosphonic acid, 12-pentafluorophenoxydodecylphosphonic acid, 1H,1H,2H,2H-perfluorododecyl phosphonic acid, octadecylphosphonic acid, or combinations thereof.
